(19) United States
(12) Patent Application Publication
(10) Pub. No.: US 2009/0167371 A1
(43) Pub. Date: Jul. 2, 2009

(54) CAPACITIVE LOAD DRIVING CIRCUIT

(75) Inventors: Hiroshi Ando, Osaka (JP); Akihiro Maejima, Osaka (JP); Hiroki Matsunaga, Osaka (JP); Jinsaku Kaneda, Osaka (JP); Eisaku Maeda, Osaka (JP)

Correspondence Address: Dickinson Wright PLLC;James E. Ledbetter, Esq., International Square, 1875 Eye Street, N.W., Suite 1200, Washington, DC, 20006, US

(73) Assignee: MATSUSHITA ELECTRIC INDUSTRIAL CO., LTD., OSAKA (JP)

(21) Appl. No.: 11/720,507

(22) PCT Filed: Jan. 11, 2006
(86) PCT No.: PCT/JP2006/300188

§ 371 Date: May 30, 2007

(30) Foreign Application Priority Data
Jan. 11, 2005 (JP) 2005-003665

(51) Int. Cl. H03K 3/00

(52) U.S. Cl. 327/111

(57) ABSTRACT

It is aimed to reduce the area of an output circuit in a capacitive load driving circuit capable of high voltage output, such as a PDP scan driver for driving a plasma display panel. To achieve this, there are provided an arbitrary number of N-type MOS transistors 001, 002, . . . , and 003 including grounded sources and gates receiving a control signal, diodes 004, 005, . . . , and 006 paired with the N-type MOS transistors 001, 002, . . . , and 003, respectively, and including cathodes connected to drains of the N-type MOS transistors 001, 002, . . . , and 003 and anode, all connected to a first node 044, the number of diodes being the same as the number of N-type MOS transistors, and a first P-type MOS transistor 015 having a drain connected to the first node 044, a gate receiving a control signal and a source connected to a high voltage source.

### TECHNICAL FIELD

The present invention relates to capacitive load driving circuits capable of high voltage output, which include a scan driver for driving a plasma display panel (hereinafter abbreviated as “PDP”).

### BACKGROUND ART

As shown in FIG. 6, a conventional capacitive load driving circuit, which is mainly used as a scan driver for driving a PDP, includes an arbitrary number of N-type MOS transistors 201, 202, . . . , and 203 (here, sixty-four of them), an arbitrary number of P-type MOS transistors 204, 205, . . . , and 206 (here, sixty-four of them) and a timing generation circuit 207.

The sixty-four N-type MOS transistors 201, 202, . . . , 203 include grounded sources, gates receiving control signals N1, N2, . . . , N64 via control signal lines 211, 212, . . . , 213, respectively, and drains serving as output terminals 217, 218, . . . , 219 (output signals OUT1 to OUT64) connected to capacitive loads 220, 221, . . . , 222, respectively.

The sixty-four P-type MOS transistors 204, 205, . . . , and 206 are paired with the N-type MOS transistors 201, 202, . . . , and 203, respectively. Further, the sixty-four P-type MOS transistors 204, 205, . . . , and 206 include drains connected to their corresponding drains of the N-type MOS transistors 201, 202, . . . , and 203, gates receiving control signals P1, P2, . . . , and P64 via control signal lines 214, 215, . . . , and 216, respectively, and sources connected to a high voltage source terminal 210 (a voltage VDDH).

The timing generation circuit 207 has a data signal input terminal 208 to which a data signal DATA is externally inputted, and a clock signal input terminal 209 to which a clock signal CLK is externally inputted. Further, the timing generation circuit 207 generates the control signals N1, N2, . . . , and N64 in accordance with the number of the arbitrary number of N-type MOS transistors 201, 202, . . . , and 203, and the control signals P1, P2, . . . , and P64 in accordance with the number of the arbitrary number of P-type MOS transistors 204, 205, . . . , and 206.

FIG. 7A illustrates a timing chart of logic signals (control signals) in the conventional capacitive load driving circuit, which is mainly used as a scan driver for driving a PDP. FIG. 7B illustrates a circuit example of the timing generation circuit 207 capable of realizing such timings.

In FIG. 7A, the control signals N1, N2, . . . , and N64 are temporally set to high level one after another in accordance with the timing of the clock signal CLK. As a result, the N-type MOS transistors 201, 202, . . . , and 203 are temporarily turned ON, so that the output signals OUT1, OUT2, . . . , and OUT64 of the output terminals 217, 218, . . . , and 219 fall from high level to low level.

Subsequently, the control signals P1, P2, . . . , and P64, which are delayed by one clock cycle, are temporarily set to low level. As a result, the P-type MOS transistors 204, 205, . . . , and 206 are turned ON, so that the output signals OUT1, OUT2, . . . , and OUT64 of the output terminals 217, 218, . . . , and 219 are set back to the original high level.

Thereafter, similar operations are performed, so that the capacitive loads 220, 221, . . . , 222 are driven one after another by the output signal OUT1 of the output terminal 217 through the output signal OUT64 of the output terminal 219.

FIG. 7B is a circuit diagram illustrating an exemplary logic circuit for generating these timings. This logic circuit uses a shift register, which is composed of D-latches 250, 251, 252, . . . , and 253 and operate in synchronization with the clock signal CLK, to delay the timing signal (the data signal DATA), thereby generating the control signals N1, N2, . . . , and N64. Also, the logic circuit delays the respective phases of the control signals N1, N2, . . . , and N64 by one clock cycle, and, furthermore, inverts them by using inversion elements 254, 255, . . . , and 256, thereby generating the control signals P1, P2, . . . , and P64. Note that the logic circuit (the timing generation circuit) does not have to be configured as above, and may be a streamlined circuit configured by a logic description so long as outputs coincide with each other.

[Patent Document 1] Japanese Laid-Open Patent Publication No. 2001-134230 (FIG. 1)

[Patent Document 2] Japanese Examined Patent Publication No. 6-91442 (FIG. 1)

### DISCLOSURE OF THE INVENTION

### Problems to be Solved by the Invention

The capacitive load driving circuit in the above BACKGROUND ART section has a P-type MOS transistor and an N-type MOS transistor for each of the output signals OUT1 through OUT64, and is provided, for example, in such specifications that a low-level voltage is fed out per output corresponding to one scanning line at the time of a PDP scanning operation, and when an output corresponding to the next scanning line provides a low-level voltage, the immediately previous output is at high level.

In such specifications, the circuit structure is large, output circuits of transistors occupy a considerably large proportion of a semiconductor chip, and therefore it is not easy to reduce the area of a chip, which controls the cost of a semiconductor.

However, in the case where a plurality of outputs are not selected and provided unless all outputs transition simultaneously, it is not necessary to include a pair of MOS transistors consisting of a P-type MOS transistor and an N-type MOS transistor for each output.

An object of the present invention is to provide a capacitive load driving circuit capable of simplifying the circuit structure and realizing cost reduction.

### Means for Solving the Problems

To solve the above problem, a capacitive load driving circuit according to the present invention includes: first switching elements grounded at one end and individually connected at the other end to a plurality of capacitive loads, the elements being provided in the same number as the plurality of capacitive loads; a second switching element connected at one end to a high voltage source; anti-backflow elements commonly connected at one end to the other end of the second switching element and individually connected at the other end to the plurality of capacitive loads, the elements being provided in the same number as the plurality of capacitive loads; and a timing generation circuit for sequentially driving the plurality of capacitive loads by generating a first control signal to allow the first switching elements provided in the same number as the plurality of capacitive loads to temporarily become conductive at their respectively different times and a second control signal to allow the second switching element to temporarily become conductive after each of the first switching elements provided in the same number as the plurality of capacitive loads is shut off.

According to this configuration, the second switching element is shared between the plurality of capacitive loads, and therefore it is possible to reduce the number of second switching elements to less than that of the plurality of capacitive loads, and the number of elements for raising the capacitive loads from a ground potential to a high voltage source potential. Consequently, it is possible to simplify the circuit structure and realize cost reduction.

The above-described capacitive load driving circuit according to the present invention preferably employs the following configuration. Specifically, the first switching elements provided in the same number as the plurality of capacitive loads are composed of N-type MOS transistors provided in the same number as the plurality of capacitive loads, the N-type MOS transistors provided in the same number as the plurality of capacitive loads including grounded sources, gates receiving the first control signal and drains connected to the plurality of capacitive loads, respectively.

Also, the anti-backflow elements provided in the same number as the plurality of capacitive loads are composed of diodes provided in the same number as the plurality of capacitive loads, the diodes provided in the same number as the plurality of capacitive loads including cathodes individually connected to drains of the N-type MOS transistors provided in the same number as the plurality of capacitive loads and anodes commonly connected to a first node.

Also, the second switching element is composed of a P-type MOS transistor, the P-type MOS transistor having a drain connected to the first node, a gate receiving the second control signal and a source connected to the high voltage source.

Also, the timing generation circuit generates the first control signal and the second control signal at such times as to sequentially drive the plurality of capacitive loads.

According to this configuration, the second switching element is shared between the plurality of capacitive loads, and therefore it is possible to reduce the number of second switching elements to less than that of the plurality of capacitive loads, and the number of elements for raising the capacitive loads from a ground potential to a high voltage source potential. Consequently, it is possible to simplify the circuit structure and realize cost reduction.

Also, the above-described capacitive load driving circuit of the present invention may employ the following configuration. Specifically, the plurality of capacitive loads are arranged in a row consisting of an arbitrary number of capacitive loads, the arbitrary number being a multiple of 4.

Also, the first switching elements provided in the same number as the plurality of capacitive loads are composed of N-type MOS transistors provided in the same number as the plurality of capacitive loads, the N-type MOS transistors provided in the same number as the plurality of capacitive loads including grounded sources, gates receiving the first control signal and drains connected to the plurality of capacitive loads, respectively.

Also, the anti-backflow elements provided in the same number as the plurality of capacitive loads are composed of diodes provided in the same number as the plurality of capacitive loads, the diodes provided in the same number as the plurality of capacitive loads including cathodes individually connected to drains of the N-type MOS transistors provided in the same number as the plurality of capacitive loads.

Also, in order to set a subsequent output in output order of a sequence of the plurality of capacitive loads arranged in a row to correspond to a multiple of 4, the capacitive loads are separated into four groups, such that a K-th output and a (k+4L)-th output (where k and L are an integer equal to 1 or more) are not provided next to each other, and the diodes provided in the same number as the plurality of capacitive loads are such that anodes of diodes corresponding to a first group are commonly connected to a first node, anodes of diodes corresponding to a second group are commonly connected to a second node, anodes of diodes corresponding to a third group are commonly connected to a third node, and anodes of diodes corresponding to a fourth group are commonly connected to a fourth node.

Also, the second switching element is composed of first, second, third and fourth P-type MOS transistors, the first P-type MOS transistor having a drain connected to the first node, a gate receiving a third control signal included in the second control signal and a source connected to the high voltage source, the second P-type MOS transistor having a drain connected to the second node, a gate receiving a fourth control signal included in the second control signal and a source connected to the high voltage source, the third P-type MOS transistor having a drain connected to the third node, a gate receiving a fifth control signal included in the second control signal and a source connected to the high voltage source, the fourth P-type MOS transistor having a drain connected to the fourth node, a gate receiving a sixth control signal included in the second control signal and a source connected to the high voltage source.

Also, the timing generation circuit generates the third control signal, the fourth control signal, the fifth control signal and the sixth control signal in skipping output order without allowing N-type MOS transistors corresponding to capacitive loads in the same group to become conductive in a consecutive manner and allowing adjacent elements to perform output sequentially, the third control signal allowing the first P-type MOS transistor to temporarily become conductive after each N-type MOS transistor corresponding to the capacitive loads in the first group is shut off, the fourth control signal allowing the second P-type MOS transistor to temporarily become conductive after each N-type MOS transistor corresponding to the capacitive loads in the second group is shut off, the fifth control signal allowing the third P-type MOS transistor to temporarily become conductive after each N-type MOS transistor corresponding to the capacitive loads in the third group is shut off, the sixth control signal allowing the fourth P-type MOS transistor to temporarily become conductive after each N-type MOS transistor corresponding to the capacitive loads in the fourth group is shut off.

According to this configuration, it is possible to allow outputting in skipping order, rather than by switching timing, and reduce the number of elements for raising the capacitive loads from a ground potential to a high voltage source potential.

### EFFECT OF THE INVENTION

Thus, as described above, the capacitive load driving circuit according to the present invention mainly used as a PDP scan driver and capable of driving capacitive loads is configured to include one second switching element, making it possible to considerably reduce an area occupied by the circuit.

Also, by using a plurality of P-type MOS transistors as the second switching element or using 4 or more P-type MOS transistors as the second switching element, it is made possible to suppress through-current, which is caused by simultaneously turning ON the second switching element and the first switching elements, without complicating a timing circuit, and allow the output order to be arbitrary designed even in the case of skipping order, making it possible to be compatible with various output specifications.

Thus, in addition to reducing the area occupied by the circuit, it is possible to improve the image quality of a PDP panel, and improve the reliability of the PDP scan driver and the PDP panel.

### BRIEF DESCRIPTION OF THE DRAWINGS

FIG. 1 is a circuit diagram illustrating the configuration of a capacitive load driving circuit according to a first embodiment of the present invention.

FIG. 2A is a timing chart showing exemplary logic timings generated in a timing generation circuit according to the first embodiment of the present invention.

FIG. 2B is a circuit diagram illustrating an exemplary logic circuit capable of realizing the exemplary logic timings in FIG. 2A.

FIG. 3 is a schematic diagram showing an operation example between adjacent outputs according to the first embodiment of the present invention.

FIG. 4 is a circuit diagram illustrating the configuration of a capacitive load driving circuit according to a second embodiment of the present invention.

FIG. 5A is a timing chart showing exemplary logic timings generated in a timing generation circuit according to the second embodiment of the present invention.

FIG. 5B is a circuit diagram illustrating an exemplary logic circuit capable of realizing the exemplary logic timings in FIG. 5A.

FIG. 6 is a circuit diagram illustrating the configuration of a conventional capacitive load driving circuit used in a PDP scan driver.

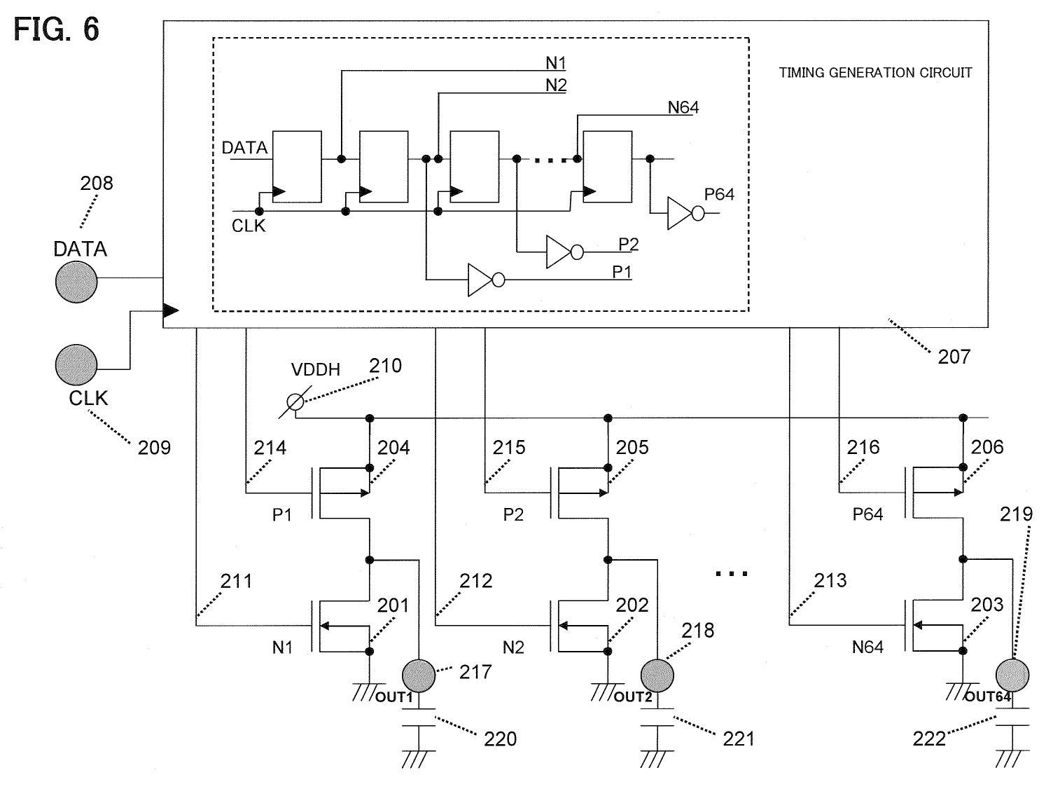

FIG. 7A is a timing chart showing exemplary logic timings generated in a timing generation circuit of the capacitive load driving circuit in FIG. 6.

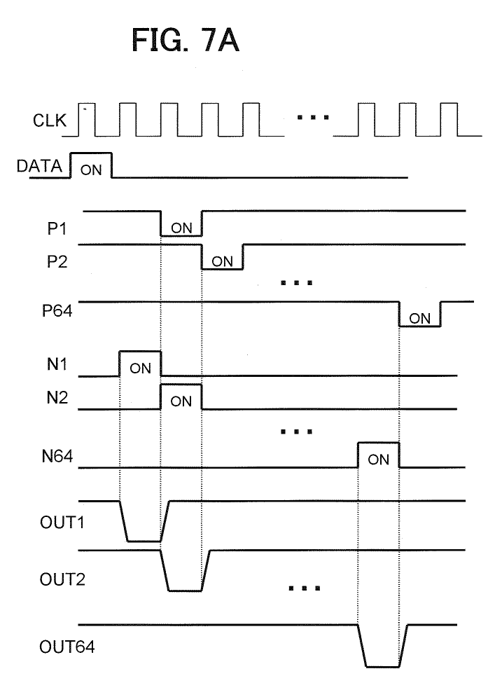

FIG. 7B is a circuit diagram illustrating an exemplary logic circuit capable of realizing the exemplary logic timings in FIG. 7A.

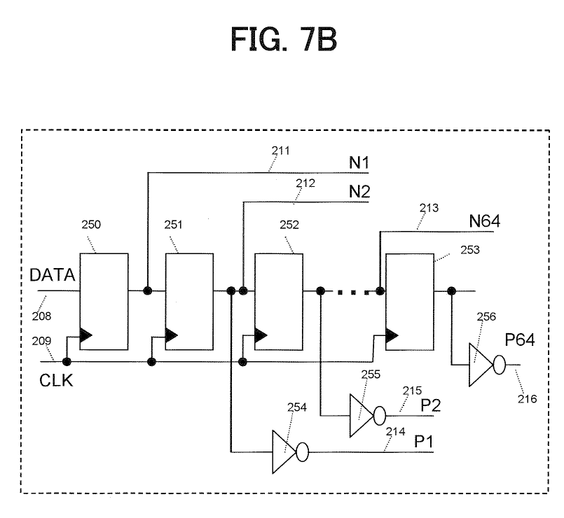

### DESCRIPTION OF THE REFERENCE CHARACTERS

001-003, 100-107, 201-203 N-type MOS transistor
007, 116-119, 204-206 P-type MOS transistor
012-014, 124-131, 211-213 control signal line for N-type MOS transistor
015, 132-135, 214-216 control signal line for P-type MOS transistor
041-043, 181-188, 220-222 capacitive load
044, 189 first node
190 second node
191 third node
192 fourth node
004-006, 108-115 diode
008, 120, 207 timing generation circuit
009, 121, 208 data pulse input terminal
010, 122, 209 clock input terminal
011, 123, 210 high voltage source terminal
016-018, 136-143, 217-219 output terminal
020-027, 150-158, 250-253 D-latches included in shift register
028, 029, 031, 033, 035, 159-166, 254-256 inversion element
030, 032, 034, 036, 037, 038, 039, 040, 167-170 logic element

### BEST MODE FOR CARRYING OUT THE INVENTION

Hereinafter, embodiments of the present invention will be described with reference to the drawings.

### First Embodiment

An embodiment of the present invention is described below with reference to the drawings.

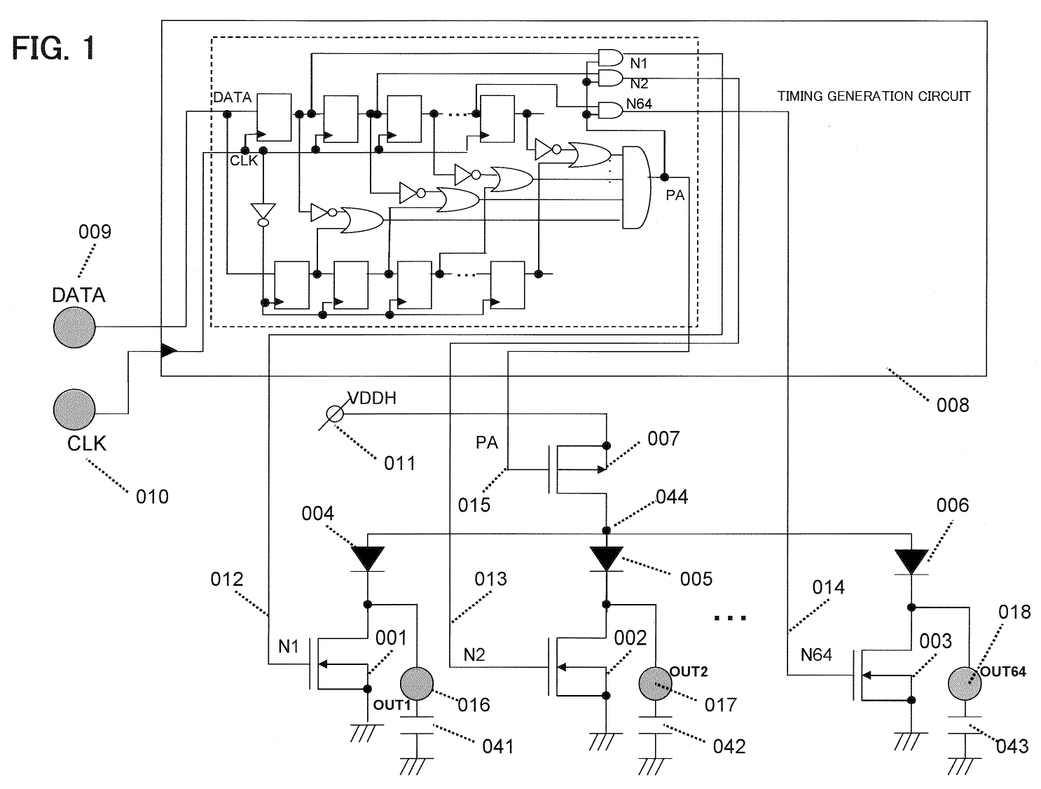

FIG. 1 is a circuit diagram illustrating the configuration of a capacitive load driving circuit according to a first embodiment of the present invention, which is mainly used as a scan driver for driving a PDP. Here, a sixty-four-output circuit is described.

In FIG. 1, numerals 001, 002, . . . , and 003 denote N-type MOS transistors, which are first switching elements. Numerals 004, 005, . . . , and 006 denote diodes, which are anti-backflow elements coupled to the N-type MOS transistors 001, 002, . . . , and 003, respectively. Numeral 007 denotes a P-type MOS transistor, which is a second switching element. Numerals 016, 017, . . . , and 018 denote output terminals for outputting output signals (capacitive load drive signals) OUT1, OUT2, . . . , and OUT64 respectively derived from junction points between drains of the N-type MOS transistors 001, 002, . . . , and 003 and cathodes of the diodes 004, 005, and 006. Numeral 044 denotes a first node, which connects the P-type MOS transistor 007 to all anodes of the diodes 004, 005, . . . , and 006. Numeral 008 denotes a timing generation circuit for controlling the output signals OUT1 through OUT64. Numeral 009 denotes a data signal input terminal for inputting a data signal DATA to the timing generation circuit 008, which is a logic circuit. Numeral 010 denotes a clock signal input terminal for inputting a clock signal CLK to drive the timing generation circuit 008. Numerals 041, 042 and 043 denote capacitive loads in the form of cells in a PDP panel. Numerals 012, 013 and 014 denote control signal lines for inputting control signals N1, N2, . . . , and N64 from the timing generation circuit 008 to gates of the N-type MOS transistors 001, 002, . . . , and 003. Numeral 015 denotes a control signal line for inputting a control signal PA from the timing generation circuit 008 to a gate of the P-type MOS transistor 007. Numeral 011 denotes a high voltage source terminal for applying a source voltage VDDH to the P-type MOS transistor 007.

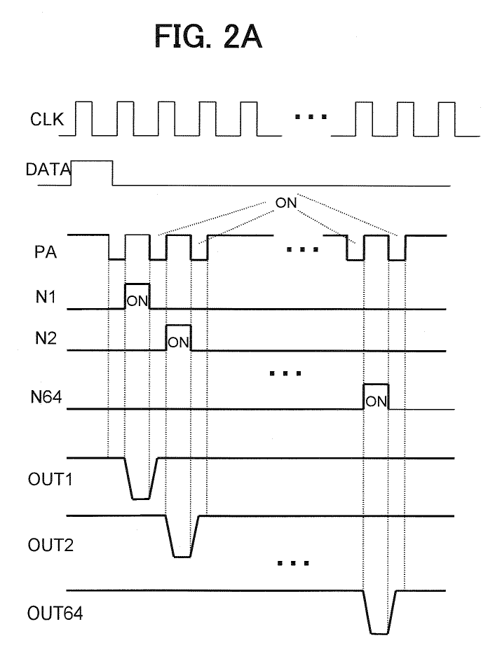

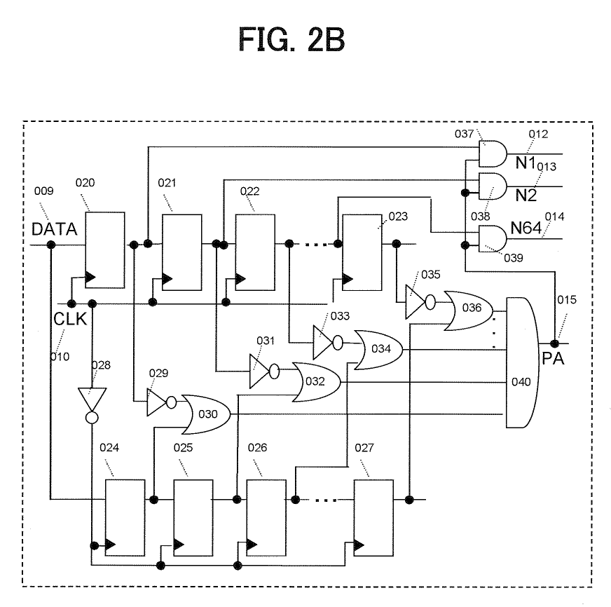

An operation example of the circuit in FIG. 1 is described with reference to FIGS. 2A and 2B. FIG. 2A shows timings of control signals (logic signals) in the capacitive load driving circuit according to the first embodiment of the present invention. FIG. 2B illustrates an exemplary circuit capable of realizing such timings.

In FIG. 2B, numerals 029, 031, 033, . . . , and 035 denote inversion elements, numerals 030, 032, 034, . . . , and 036 denote logic elements, and numerals 037, 038, . . . , 039, and 040 denote logic elements.

In FIGS. 2A and 2B, a data signal DATA is delayed in units of clocks by a shift register composed of D-latches 020, 021, 022, . . . , and 023 in accordance with the timing of a clock signal CLK. As a result, a data pulse shifted in timing in units of clocks is outputted from each of the D-latches 020, 021, 022, . . . , and 023.

Also, the clock signal CLK is inverted by the inversion element 028, thereby generating an inverted clock signal. In accordance with the timing of the inverted clock signal, the data signal DATA is delayed in unit of clocks by a shift register composed of D-latches 024, 025, 026, . . . , and 027. As a result, a data pulse shifted in timing in unit of clocks is outputted from each of the D-latches 024, 025, 026, . . . , and 027.

Here, the data pulses outputted from the D-latches 024, 025, 026, . . . , and 027 are shifted in phase with respect to the data pulses outputted from the D-latches 020, 021, 022, . . . , and 023. The difference in phase corresponds to the difference between the rise and fall times of the clock signal. The time corresponds to, for example, about half the width of a clock cycle.

Inverted data pulses that are obtained by inverting the data pulses outputted from the D-latches 020, 021, 022, . . . , and 023 by the inversion elements 29, 31, 33, . . . , and 35 are ORed with the data pulses outputted from the D-latches 024, 025, 026, . . . , and 027, respectively, by the logic elements 030, 032, 034, . . . , and 036, and outputs of the logic elements 030, 032, 034, . . . , and 036 are ANDed together by the logic element 40, thereby generating a control signal PA. The control signal PA is used to raise output signals OUT1 through OUT64, which have fallen to low level, to high level.

Also, the data pulses outputted from the D-latches 020, 021, 022, . . . , and 023 are ANDed with the control signal PA by using the logic elements 037, 038, . . . , and 039, to perform wave form shaping for masking rising periods of the data pulses outputted from the D-latches 020, 021, 022, . . . , and 023, and thereby to generate control signals N1, N2, . . . , and N64. With the control signals N1, N2, . . . , and N64, the output signals OUT1 through OUT64 are set to low level. As a result, the upper P-type MOS transistor 007 and the lower N-type MOS transistors 001, 002, . . . , and 003 are caused not to be turned ON at the same time.

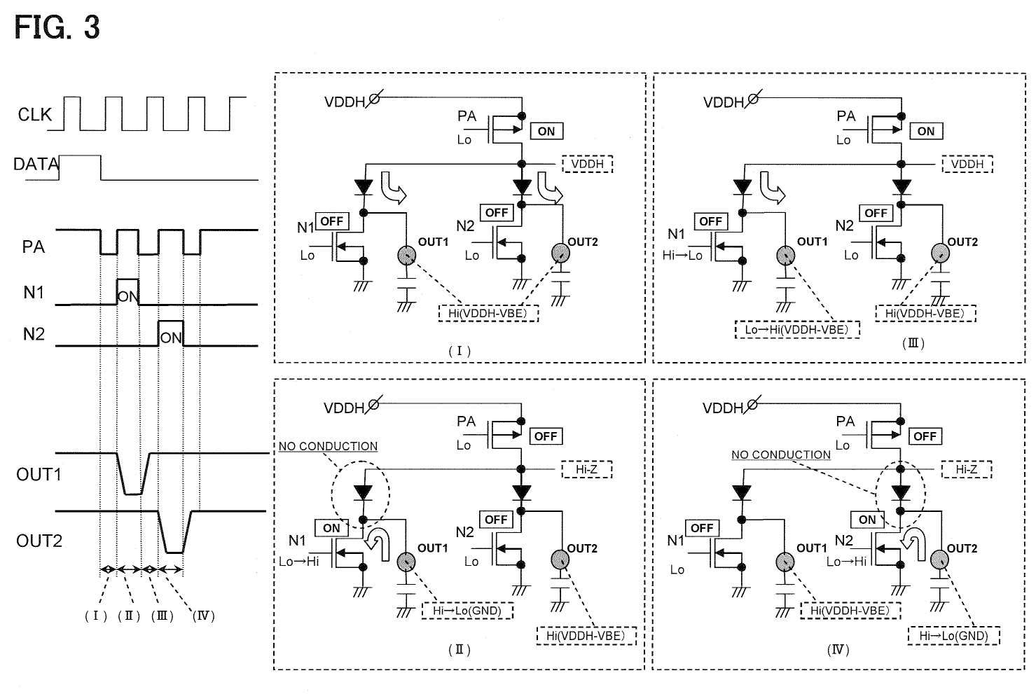

Referring to FIG. 3, an actual operation between adjacent outputs is described.

In the period of (I), the upper P-type MOS transistor is turned ON to store electric charge in capacitive loads.

In the period of (II), the first lower N-type MOS transistor is turned ON simultaneously with the turning OFF of the upper P-type MOS transistor, so that an output signal OUT1 connected to the lower N-type MOS transistor is set to low level. At this time, a cathode of a diode connected to a drain of the lower N-type MOS transistor falls to ground level. However, an anode has nothing to draw electric current, and therefore no current flows to the diode. Accordingly, another adjacent output signal OUT2 is not affected.

Next, in the period of (III), the upper P-type MOS transistor is turned ON simultaneously with the turning OFF of the first lower N-type MOS transistor, to supply an approximately high voltage source to the anode side of a diode, and thereby to charge the output signal OUT1 connected to the first lower N-type MOS transistor from low level, i.e., ground level, to a voltage lower than the voltage VDDH of the high voltage source by a forward voltage (VBE) of the diode, so that the output signal OUT1 is set back to high level.

Further, in the period of (IV), as in the period of (II), the second lower N-type MOS transistor is turned on simultaneously with the turning OFF of the upper P-type MOS transistor, so that an output signal OUT2 connected to the lower N-type MOS transistor is set to low level. At this time, a cathode of a diode connected to a drain of the N-type MOS transistor falls to ground level, but an anode has nothing to draw electric current, and therefore no current flows to the diode.

With the above operation, it is possible to set output terminals connected to a capacitive load to low level one by one, while retaining other outputs at high level.

Thus, according to the first embodiment, it is possible to set the number of P-type MOS transistors for raising to high level to one, and minimize the area. Also, the timing generation circuit (the logic circuit) 008 does not have to be configured as above, and may be a streamlined circuit configured by a logic description so long as outputs coincide each other.

### Second Embodiment

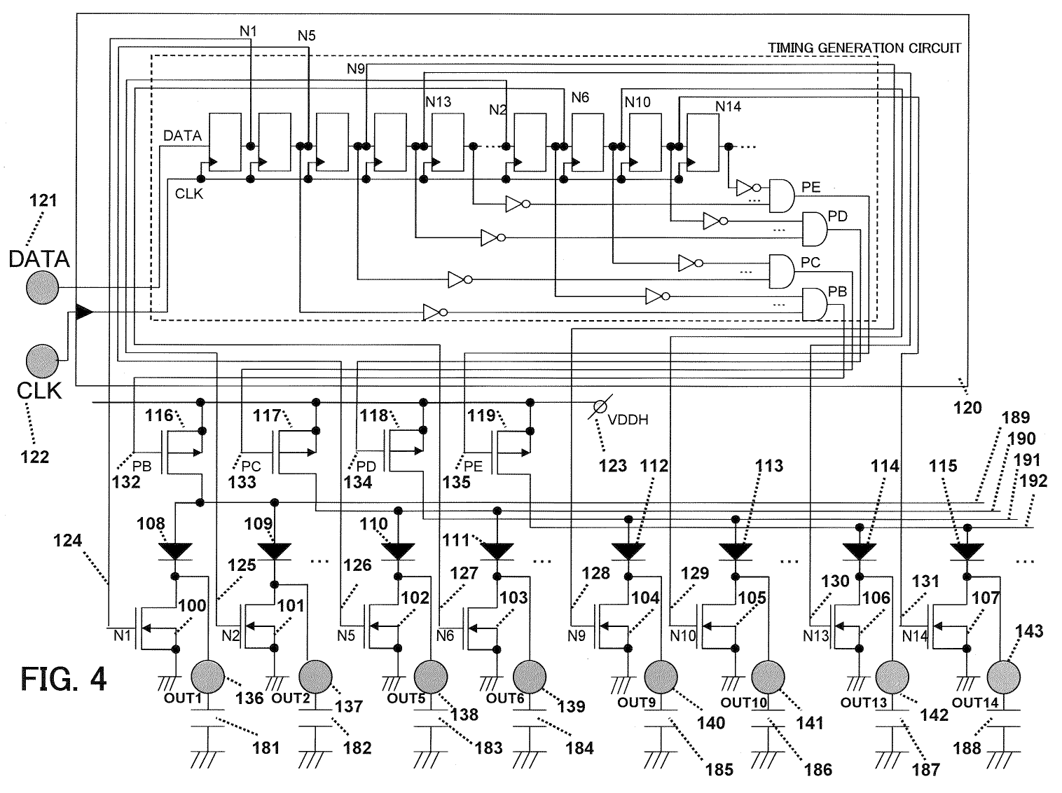

FIG. 4 is a circuit diagram illustrating the configuration of a capacitive load driving circuit according to a second embodiment of the present invention, which is mainly used as a scan driver for driving a PDP, and described here is a J-output circuit, where J is an arbitrary multiple of 4.

In FIG. 4, numerals 100 through 107 denote N-type MOS transistors.

Numerals 108 through 115 denote diodes connected to the N-type MOS transistors 100 through 107, respectively.

Numeral 116 denotes a P-type MOS transistor in which an anode of each diode in sets of the N-type MOS transistors 100, 101, . . . and the diodes 108, 109, . . . is connected to a first node 189.

Numeral 117 denotes a P-type MOS transistor in which an anode of each diode in sets of the N-type MOS transistors 102, 103, . . . and the diodes 110, 111, . . . is connected to a second node 190.

Numeral 118 denotes a P-type MOS transistor in which an anode of each diode in sets of the N-type MOS transistors 104, 105, . . . and the diodes 112, 113, . . . is connected to a third node 191.

Numeral 119 denotes a P-type MOS transistor in which an anode of each diode in sets of the N-type MOS transistors 106, 107, . . . and the diodes 114, 115, . . . is connected to a fourth node 192.

Numerals 136 through 143 denote output terminals for outputting output signals OUT1 through OUTJ respectively derived from junction points between drains of the N-type MOS transistors 100 through 107 and cathodes of the diodes 108 through 115. Note that in FIG. 4, only the output signals OUT1, OUT2, OUTS, OUT6, OUT9, OUT10, OUT13 and OUT14 are shown, and the illustration of other signals is omitted.

Numerals 181 through 188 denote capacitive loads that are to be driven.

Numeral 120 denotes a timing generation circuit for controlling output signals. Numeral 121 denotes a data input terminal for inputting an input data signal DATA to the timing generation circuit 120, which is a logic circuit.

Numeral 122 denotes a clock input terminal for inputting a clock signal CLK to drive the timing generation circuit 120.

Numerals 124 through 131 denote control signal lines for supplying control signals N1 through NJ to the N-type MOS transistors 100 through 107. Note that in FIG. 4, only the control signals N1, N2, N5, N6, N9, N10, N13 and N14 are shown, and the illustration of other signals is omitted.

Numerals 132 through 135 denote control signal lines for supplying control signals PB, PC, PD and PE to the P-type MOS transistors 116 through 119.

Numeral 123 denotes a high voltage source terminal for providing a source voltage VDDH to the P-type MOS transistors 116 through 119.

In order to provide outputs in such an order that, for each of the four nodes 189, 190, 191 and 192, one output is followed by the next output but three (e.g., 1, 5, 9, 13, . . . , (J-3); 2, 6, 10, 14 . . . , (J-2); 3, 7, 11, 15 . . . , (J-1); 4, 8, 12, 16 . . . , J), the outputs are connected to the four nodes, such that a K-th output and a (k+4)-th output (where k is an arbitrary integer), i.e., the first and fifth outputs, are not provided next to each other; in this embodiment, a sequence of four outputs are provided, such that the first, second, third and fourth outputs are connected to the first node 189, the next sequence of four outputs, i.e., the fifth, sixth, seventh and eighth outputs, are connected to the second node 190, the next sequence but one, i.e., the ninth, tenth, eleventh and twelfth outputs, are connected to the third node 191, and the next sequence but two, i.e., the thirteenth, fourteenth, fifteenth and sixteenth outputs are connected to the fourth node 192.

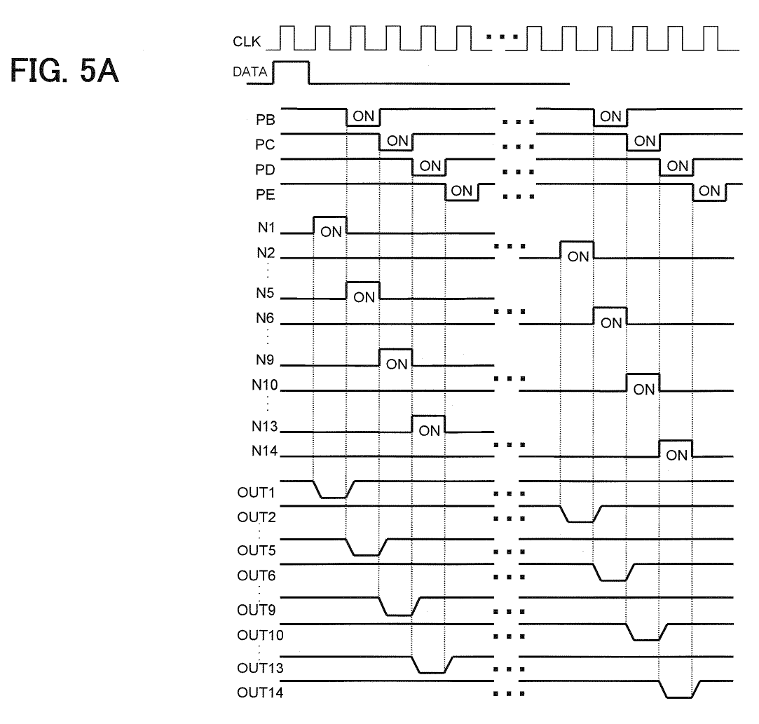

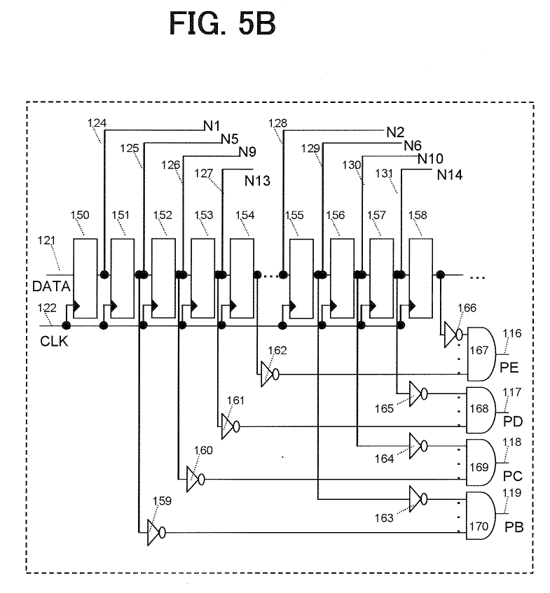

An operation example of the circuit in FIG. 4 is described with reference to FIGS. 5A and 5B. FIG. 5A shows timings of control signals in the capacitive load driving circuit according to the second embodiment of the present invention. FIG. 5B illustrates an exemplary circuit capable of realizing such timings.

As shown in FIGS. 5A and 5B, a data signal DATA is delayed in units of clocks by a shift register composed of D-latches 150, 151, 152, 153, 154, . . . , 155, 156, 157, 158, . . . in accordance with the timing of a clock signal CLK, thereby generating control signals N1, N2, . . . , N5, N6, . . . , N9, N10, . . . , N13 and N14. Specifically, the delay in units of clocks by the shift register composed of the D-latches 150, 151, 152, 153, 154, . . . , 155, 156, 157, 158, . . . determines the times to turn ON the lower N-type MOS transistors 100, 101, . . . , 102, 103, . . . , 104, 105, . . . , 106 and 107 in order to set the output signals OUT1 through OUTJ to low level.

Also, data pulses delayed by one clock cycle from ON timings of the lower N-type MOS transistors 100, 101, . . . , 102, 103, . . . , 104, 105, . . . , 106 and 107 are logically processed by inversion elements 159, . . . , 163, 160, . . . , 164, 161, . . . , 165, 162, . . . , and 166 and logic elements 167, 168, 169 and 170 to generate control signals PB, PC, PD and PE. Specifically, the ON timings of the four P-type MOS transistors 116, 117, 118 and 119 for setting the output signals OUT1 through OUTJ to high level are determined by logically processing the above outputs of the shift register.

In this case, the next N-type MOS transistor that is to be turned ON is not connected to a P-type MOS transistor that sets a lower N-type MOS transistor, which has been set to low level, back to high level. Therefore, the times to turn ON the P-type MOS transistors in order to set the output signals OUT1 through OUTJ, which have temporarily fallen to low level, back to high level, can be the same as the time to turn ON the next N-type MOS transistor.

Accordingly, without being controlled by the odd/even timing and considerably changing the configuration of the output circuit portion (excluding the timing generation circuit), it is possible to allow easy adaptation to the outputting in skipping order, such as 1, 5, 9, 13, . . . , 61; 2, 6, 10, 14, . . . , and skipping intervals can be arbitrarily selected so long as they consist of the number of upper P-type transistors (here a multiple of 4). Also, the outputting in sequential order, such as 1, 2, 3, . . . , is made possible by changing the wiring of the timing generation circuit 120, etc., without considerably changing the configuration.

Thus, according to the second embodiment, by providing the four P-type MOS transistors 116, 117, 118 and 119, it is made possible to more readily configure the logic circuit compared to the first embodiment, while keeping the chip area small, and, further, to allow the outputting in skipping order without being constrained by order, e.g., one-by-one sequence, odd or even. Further, by changing the number of upper P-type MOS transistors, the skipping intervals can be arbitrarily changed. Furthermore, the logic circuit does not have to be configured as above, and may be a streamlined circuit configured by a logic description so long as outputs coincide with each other.

As described above, according to each embodiment of the present invention, a transistor for storing electric charge in a capacitive load is shared between a plurality of capacitive loads to reduce the number of transistors for storing electric charge in a capacitive load, whereby it is possible to reduce the area of a driving circuit.

Also, in addition to allowing the reduction for the driving circuit, it is possible to allow interlaced scanning at intervals consisting of a multiple of 4.

### INDUSTRIAL APPLICABILITY

A capacitive load driving circuit according to the present invention achieves effects of simplifying the circuit configuration and allowing arbitrary selection of scanning order, and therefore is useful, for example, as a scan driver for driving a plasma display panel (hereinafter “PDP”).

1. A capacitive load driving circuit comprising:
first switching elements grounded at one end and individually connected at the other end to a plurality of capacitive loads, the elements being provided in the same number as the plurality of capacitive loads;
a second switching element connected at one end to a high voltage source;
anti-backflow elements commonly connected at one end to the other end of the second switching element and individually connected at the other end to the plurality of capacitive loads, the elements being provided in the same number as the plurality of capacitive loads; and
a timing generation circuit for sequentially driving the plurality of capacitive loads by generating a first control signal to allow the first switching elements provided in the same number as the plurality of capacitive loads to temporarily become conductive at their respectively different times and a second control signal to allow the second switching element to temporarily become conductive after each of the first switching elements provided in the same number as the plurality of capacitive loads is shut off.

2. The capacitive load driving circuit according to claim 1,
wherein the first switching elements provided in the same number as the plurality of capacitive loads are composed of N-type MOS transistors provided in the same number as the plurality of capacitive loads, the N-type MOS transistors provided in the same number as the plurality of capacitive loads including grounded sources, gates receiving the first control signal and drains connected to the plurality of capacitive loads, respectively,
the anti-backflow elements provided in the same number as the plurality of capacitive loads are composed of diodes provided in the same number as the plurality of capacitive loads, the diodes provided in the same number as the plurality of capacitive loads including cathodes individually connected to drains of the N-type MOS transistors provided in the same number as the plurality of capacitive loads and anodes commonly connected to a first node,
the second switching element is composed of a P-type MOS transistor, the P-type MOS transistor having a drain connected to the first node, a gate receiving the second control signal and a source connected to the high voltage source, and
the timing generation circuit generates the first control signal and the second control signal at such times as to sequentially drive the plurality of capacitive loads.

3. The capacitive load driving circuit according to claim 1,
wherein the plurality of capacitive loads are arranged in a row consisting of an arbitrary number of capacitive loads, the arbitrary number being a multiple of 4,
the first switching elements provided in the same number as the plurality of capacitive loads are composed of N-type MOS transistors provided in the same number as the plurality of capacitive loads, the N-type MOS transistors provided in the same number as the plurality of capacitive loads including grounded sources, gates receiving the first control signal and drains connected to the plurality of capacitive loads, respectively,
the anti-backflow elements provided in the same number as the plurality of capacitive loads are composed of diodes provided in the same number as the plurality of capacitive loads, the diodes provided in the same number as the plurality of capacitive loads including cathodes individually connected to drains of the N-type MOS transistors provided in the same number as the plurality of capacitive loads,
in order to set a subsequent output in output order of a sequence of the plurality of capacitive loads arranged in a row to correspond to a multiple of 4, the capacitive loads are separated into four groups, such that a K-th output and a (k+4L)-th output (where k and L are an integer equal to 1 or more) are not provided next to each other, and the diodes provided in the same number as the plurality of capacitive loads are such that anodes of diodes corresponding to a first group are commonly connected to a first node, anodes of diodes corresponding to a second group are commonly connected to a second node, anodes of diodes corresponding to a third group are commonly connected to a third node, and anodes of diodes corresponding to a fourth group are commonly connected to a fourth node,
the second switching element is composed of first, second, third and fourth P-type MOS transistors, the first P-type MOS transistor having a drain connected to the first node, a gate receiving a third control signal included in the second control signal and a source connected to the high voltage source, the second P-type MOS transistor having a drain connected to the second node, a gate receiving a fourth control signal included in the second control signal and a source connected to the high voltage source, the third P-type MOS transistor having a drain connected to the third node, a gate receiving a fifth control signal included in the second control signal and a source connected to the high voltage source, the fourth P-type MOS transistor having a drain connected to the fourth node, a gate receiving a sixth control signal included in the second control signal and a source connected to the high voltage source; and
the timing generation circuit generates the third control signal, the fourth control signal, the fifth control signal and the sixth control signal in skipping output order without allowing N-type MOS transistors corresponding to capacitive loads in the same group to become conductive in a consecutive manner and allowing adjacent elements to perform output sequentially, the third control signal allowing the first P-type MOS transistor to temporarily become conductive after each N-type MOS transistor corresponding to the capacitive loads in the first group is shut off, the fourth control signal allowing the second P-type MOS transistor to temporarily become conductive after each N-type MOS transistor corresponding to the capacitive loads in the second group is shut off, the fifth control signal allowing the third P-type MOS transistor to temporarily become conductive after each N-type MOS transistor corresponding to the capacitive loads in the third group is shut off, the sixth control signal allowing the fourth P-type MOS transistor to temporarily become conductive after each N-type MOS transistor corresponding to the capacitive loads in the fourth group is shut off.
